(19) United States
(12) Patent Application Publication
(10) Pub. No.: US 2013/0256843 A1
(43) Pub. Date: Oct. 3, 2013

(54) WAFER SAWING METHOD AND WAFER STRUCTURE BENEFICIAL FOR PERFORMING THE SAME

(71) Applicants: Hsin-Yu CHEN, Nantou County (TW); Home-Been Cheng, Keelung City (TW); Ching-Li Yang, Pingtung County (TW)

(72) Inventors: Hsin-Yu CHEN, Nantou County (TW); Home-Been Cheng, Keelung City (TW); Ching-Li Yang, Pingtung County (TW)

(73) Assignee: UNITED MICROELECTRONICS CORPORATION, HSINCHU (TW)

(21) Appl. No.: 13/438,007

(22) Filed: Apr. 3, 2012

(51) Int. Cl. H01L 29/02; H01L 21/78

(52) U.S. Cl. 257/622; 438/464; 257/E21.599; 257/E29.002

(57) ABSTRACT

A wafer sawing method comprises steps as follows: A wafer having a first surface and a second surface is firstly provided. An integrated circuit fabricating process is performed on the first surface of the wafer to define a first integrated circuit region and a periphery region surrounding around the first integrated circuit region, wherein the integrated circuit fabricating process includes an etching process used to form a first deep trench having an aspect ratio larger than 10 as well as a depth substantially ranging from one-third to two-third thickness of the wafer on the periphery region. Subsequently, an adhesive tape is disposed on the first surface at least covering the first integrated circuit region and the periphery region. A tensile stress is then imposed on the adhesive tape in order to make the wafer broken off along the first deep trench.

### FIELD OF THE INVENTION

The present invention relates to a wafer treating method and a wafer structure beneficial for performing the same, and more particularly to a wafer sawing method and a wafer structure beneficial for performing the same.

### BACKGROUND OF THE INVENTION

In a wafer sawing process for dicing a wafer into a plurality of semiconductor chips, scribe lines predetermined on the wafer are necessary to prevent the integrated circuits (ICs) formed on the chips from being damaged. In order to increase the number of the diced chips and reduce the processing cost, scribe lines with shrink dimensions are recently adopted, thus an improved wafer sawing technology may be required. In a typical wafer sawing process, a laser is usually used to form notches within scribe regions predetermined on a backside of the wafer, and then the wafer can be divided into a plurality of chips separated from along the notches by a subsequent dicing process.

However, adopting laser technology for forming the notches is costly. Thus, how to reduce the processing cost and time of the wafer sawing process is still a challenge to the art.

### SUMMARY OF THE INVENTION

Therefore, one aspect of the present invention is to provide a wafer sawing method capable of saving processing cost and time, wherein the method comprises steps as follows: A wafer having a first surface and a second surface is firstly provided. An integrated circuit fabricating process is performed on the first surface of the wafer to define a first integrated circuit region and a periphery region surrounding around the first integrated circuit region, wherein the integrated circuit fabricating process includes an etching process used to form a first deep trench having an aspect ratio larger than 10 as well as a depth substantially ranging from one-third to two-third thickness of the wafer on the periphery region. Subsequently, an adhesive tape is disposed on the first surface at least covering the first integrated circuit region and the periphery region. A tensile stress is then imposed on the adhesive tape in order to make the wafer broken off along the first deep trench.

In one embodiment of the present invention, the etching process further comprises forming a second deep trench on the first integrated circuit region.

In one embodiment of the present invention, after the second deep trench is formed by the etching process, a dielectric material is filled into the first deep trench and the second deep trench.

In one embodiment of the present invention, the etching process is performed on the periphery region to form the first deep trench having a depth substantially equal to a half thickness of the wafer.

In one embodiment of the present invention, the first deep trench formed by the etching process has a long narrow opening disposed on the periphery region.

In one embodiment of the present invention, the first deep trench formed by the etching process comprises a plurality of deep slots separated from one another and disposed on the periphery region.

In one embodiment of the present invention, after the first deep trench is formed by the etching process, a dielectric material is filled into the first deep trench.

In one embodiment of the present invention, the integrated circuit process further comprises defining a second integrated circuit region separated from the first integrated circuit region by the periphery region.

In one embodiment of the present invention, prior to imposing the tensile stress on the adhesive tape, a polishing process is performed on the second surface of the wafer in order to reduce a thickness of the wafer.

Another aspect of the present invention is to provide a wafer structure beneficial for performing a sawing process, wherein the wafer structure comprises a wafer, a first integrated circuit region, a periphery region and a first deep trench, wherein the first integrated circuit region is disposed on a first surface of the wafer; the periphery region surrounds around the integrated circuit region; and the first deep trench is formed on the periphery region and has an aspect ratio larger than 10 as well as a depth substantially ranging from one-third to two-third thickness of the wafer.

In one embodiment of the present invention, the wafer structure further comprises a second deep trench formed on the first integrated circuit region.

In one embodiment of the present invention, the second deep trench has a depth substantially greater than that of the first deep trench.

In one embodiment of the present invention, the second deep trench has a depth substantially equal to that of the first deep trench.

In one embodiment of the present invention, a conductive material is disposed in the second deep trench.

In one embodiment of the present invention, the first deep trench has a depth substantially equal to a half thickness of the wafer.

In one embodiment of the present invention, the first deep trench has a long narrow opening.

In one embodiment of the present invention, the first deep trench comprises a plurality of deep slots separated from one other.

In one embodiment of the present invention, the wafer structure further comprises a second integrated circuit region separated from the first integrated circuit region by the periphery region.

In one embodiment of the present invention, the wafer structure further comprises a dielectric material disposed on an opening of the first deep trench.

In one embodiment of the present invention, the wafer structure further comprises a dielectric material disposed in the first deep trench and a hollow structure constituted by the dielectric material.

In one embodiment of the present invention, the wafer structure further comprises an adhesive tape disposed on the first surface of the wafer and having a dimension substantially greater than that of the wafer.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A through 1E are cross-sectional views illustrating a wafer sawing method in accordance with one embodiment of the present invention;

FIG. 1F is a cross-sectional view illustrating one step of a wafer sawing method in accordance with another embodiment of the present invention;

FIG. 2 illustrates a top view of a wafer structure used for performing a wafer sawing process in accordance with another embodiment of the present invention; and

FIG. 3 illustrates a top view of a wafer structure used for performing a wafer sawing process in accordance with a further embodiment of the present invention.

### DETAILED DESCRIPTION OF PREFERRED EMBODIMENTS

A wafer sawing method is provided to form notches on a scribe line region of a wafer during an integrated circuit fabricating process, thereby the notches and the integrated circuit can be formed simultaneously. Thus an additional laser process and equipments originally used for forming the notches can be omitted. The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

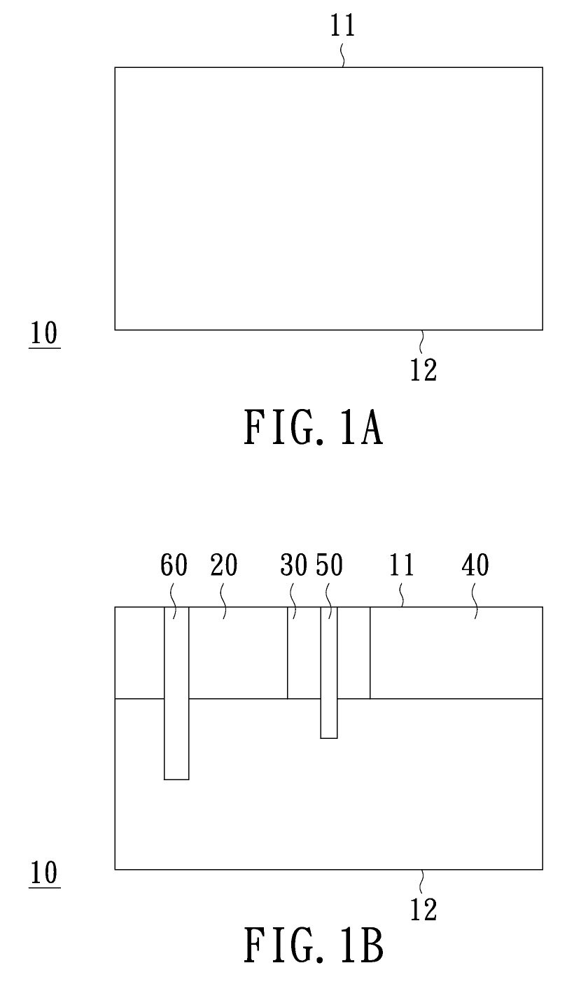

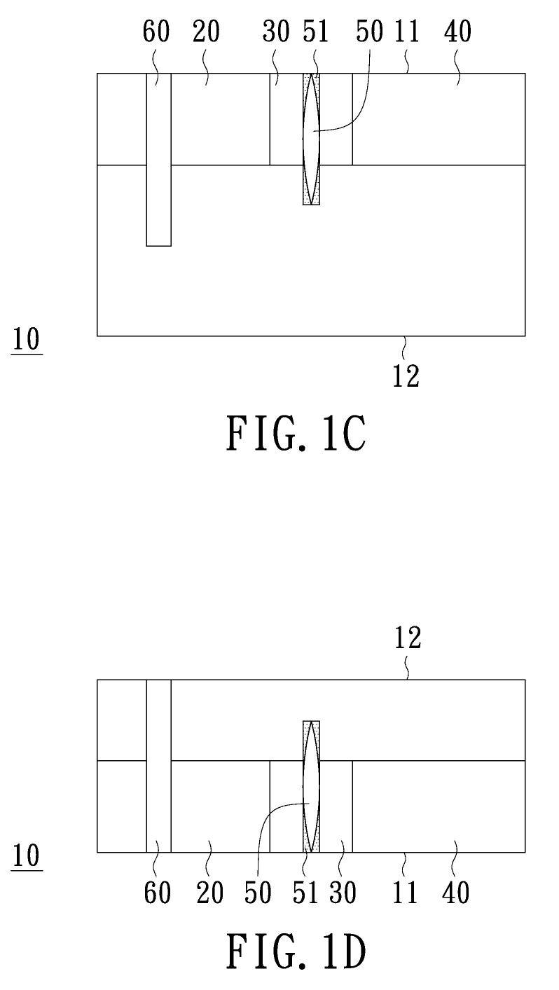

FIG. 1A through 1E are cross-sectional views illustrating a wafer sawing method in accordance with one embodiment of the present invention, wherein the wafer sawing method comprises steps as follows: Firstly referring to FIG. 1A, a wafer 10 having a first surface 11 and a second surface 12 is firstly provided. In the present embodiment, the first surface 11 is the active surface of the wafer 10 used for performing a subsequent integrated circuit fabricating process, and the second surface 12 is the backside of the wafer 10. Next, the integrated circuit fabricating process is performed on the first surface 11 of the wafer 10 to form a plurality of integrated circuit regions, such that the wafer 10 can be subsequently divided into a plurality of chips along the boundaries of the integrated circuit regions. In order to separate these integrated circuit regions from one anther, certain space, such as a periphery region surrounding the integrated circuit regions, may be preserved for allowing scribe lines formed thereon. There is a trade-off between minimizing the periphery region in order to provide more space for containing more integrated circuit regions and preserving enough space in order to prevent the integrated circuit regions from being damaged by the subsequent wafer sawing process. In the present embodiment, the width of the periphery region may be minimized about 50 μm in accordance with the practical capacities of the current technology.

Subsequently referring to FIG. 1B, the integrated circuit fabricating process of the present embodiment comprises an etching process used for forming a first deep trench 50 on the periphery region 30 capable of serving as a scribe line (notch) for dicing the wafer 10 during the subsequent wafer sawing process, wherein the first deep trench 50 is shaped as a slot with a long narrow opening and has an aspect ratio (width/depth) larger than 10 and a depth substantially ranging from one-third to two-third thickness of the wafer. The preferred depth of the first deep trench 50 may be substantially equal to a half thickness of the wafer 10.

In order to save the processing steps, the formation of the first deep trench 50 may be simultaneous to the steps for forming other semiconductor device. For example, the formation of the first deep trench 50 may be simultaneous to the steps for forming a second deep trench 60 performing on the first integrated circuit region 20 by using the same reticle during the aforementioned etching process. The second deep trench 60, for example, may be further processed to form a through-silicon via (TSV) which is used to electrically connect the integrated circuit region 20 to several chips (not shown) subsequently provided in a 3 dimension (3D) packaging technology. By this approach, since the first deep trench 50 is formed simultaneous to the process for forming the TSV, thus the processes originally designed for forming the scribe line (notch) for dicing the wafer 10 can be omitted. In other words, the scribe line (notch) can be formed on the periphery region 30 without adopting laser dicing equipments and adding any additional reticle.

In the present embodiment, the depth of the TSV may have an opening diameter substantially ranging from 6 to 25 μm and greater than that of the first deep trench 50. Besides, the second deep trench 60 may have a depth substantially greater than that of the first deep trench 50 due to micro loading effect, because the etching rate for forming a trench with a greater opening diameter may be greater than that for forming another trench with a smaller opening diameter during the same etching process.

In some embodiments of the present invention, after the second deep trench 60 is formed, a metal material may be filled in the second deep trench 60 to form the TSV in order to electrically connect the integrated circuit region 20 to the chips (not shown) which may be subsequently formed on the wafer. The first deep trench 50 which is formed on the periphery region 30 simultaneous to the formation of the second deep trench 60 serving as the scribe line (notch) for subsequently dicing the wafer 10 may be also filled with the metal material. However, because the metal material filled within the first deep trench 50 may make the first deep trench 50 hardly being broken off due to the ductility of the metal material. Thus in order to resolve these problems, in some other embodiments, after the first deep trench 50 is formed, a dielectric layer 51 or a hallow structure constituted by a dielectric material may be firstly formed in the first deep trench 50, as shown in FIG. 1C, to prevent the metal material from being filled into the first deep trench 50 during the TSV process. Further in some other embodiments of the present invention, the opening diameter of the first deep trench 50 may be controlled to a predetermined range which is small enough to prevent the metal material from being filled into the first deep trench 50 during the TSV process. Such that, the steps for forming the dielectric layer 51 covering on the first deep trench 50 may be omitted.

It should be appreciated that, the original thickness of the wafer 10 should be maintained in order to prevent the wafer 10 from being broken off during the aforementioned processes. After the integrated circuit fabricating process is carried out, the second surface 12 of the wafer 10 may be subject to a polishing process, so as to reduce the thickness of the wafer 10. In some embodiments, the second trench 60 may be broken through (see FIG. 1D) by the polishing process in order to form the TVS electrically connecting the integrated circuit region 20 with the subsequently formed chips.

In some other embodiments of the present invention (see FIG. 1F), since the first deep trench 50′ and the second deep trench 60′ which are formed by the same reticle have identical opening diameters, thus the depths of the first deep trench 50′ and the second deep trench 60′ may be controlled to an equal level after the same etching process is carried out. Such that, while the wafer 10 is ground and a through-hole passing through the second deep trench 60′ is formed during the polishing process, another through-hole passing through the first deep trench 50′ may be also formed at the same time.

In another embodiment of the present invention, the second deep trench 60 may be otherwise further processed to form a deep trench isolation (DTI) structure rather than a TSV. Similarly, the first deep trench 50 serving as the scribe line (notch) may be formed on the periphery region 30 simultaneous to the process for forming the DTI structure by using the same reticle. Thus, laser dicing equipments and additional reticles originally used for forming the scribe lines (notch) on the periphery region 30 are not necessary any more. Besides, since the process for forming the DTI structure comprises steps for forming dielectric layers, thus the aforementioned steps of forming the dielectric layer 51 used to prevent the first deep trench 50 from being filled with metal material may be integrated with the process for forming the DTI structure without adding any other additional steps. In order to integrate the process for forming the DTI and the scribe line, in the present embodiment, it is not necessary to break though the second trench 60 (as shown in FIG. 1E). In other words, the structure resulted from the polish process preferably may be similar to the structure shown in FIG. 1C.

In order to prevent the diced chips from scattering over, an adhesive tape 70, such as a ductile blue tape, is disposed on the first surface 11 of the wafer 10, wherein the adhesive tape 70 has a dimension substantially greater than that of the wafer 10. In the present embodiment, a portion of the adhesive tape 70 may extend outwards from the edge of the wafer 10, so as to allow a tensile stress S1 being imposed thereon in order to stretch the wafer 10, as shown in FIG. 1E, meanwhile the first deep trench 50 is subjected to the tensile stress S1. When the first deep trench 50 cannot sustain the tensile stress S1, the wafer 10 may be broken off along the first deep trench 50 and the wafer sawing process may be completed. Thereafter, the diced chips may be released from the adhesive tape 70, for example, by an Ultra violet (UV) light debond process.

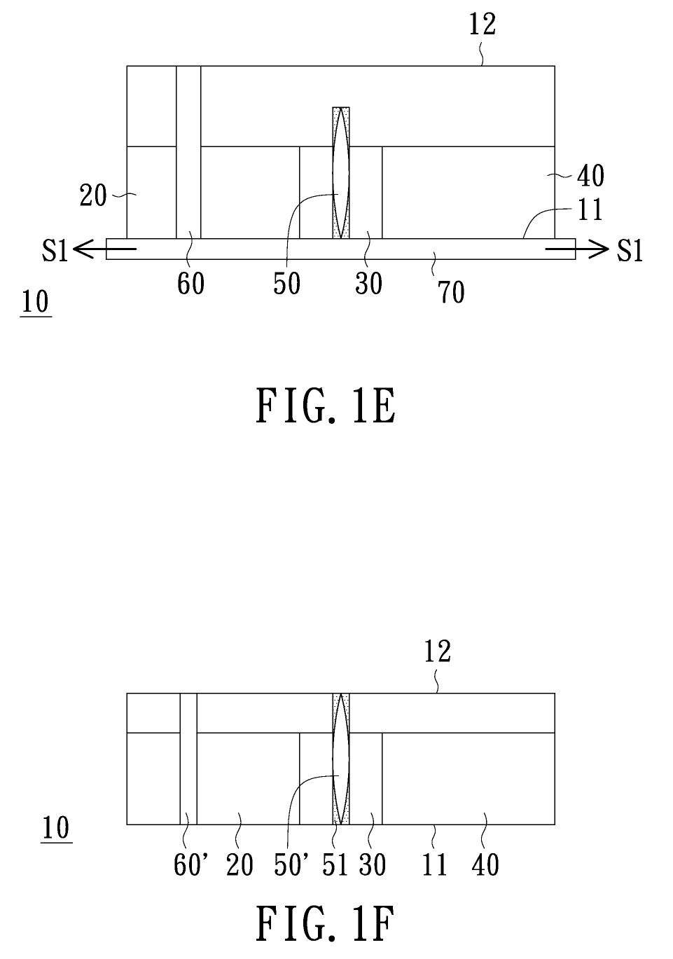

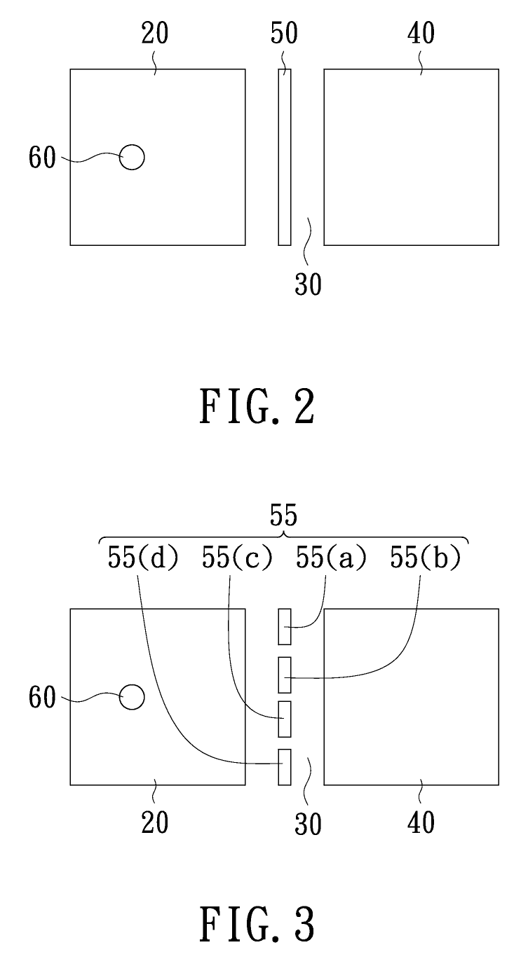

FIG. 2 illustrates a top view of a wafer structure used for performing another wafer sawing process in accordance with another embodiment of the present invention. In the present embodiment, the first deep trench 50 disposed on the periphery region 30 formed by the etching process has a long narrow opening. However, it should be appreciated that, the first deep trench 50 which is shaped as a slot having a continued and long narrow opening is just illustrated, only if the scribe lines (notches) can be formed on the periphery region 30, the shape of the first deep trench 50 is not limited. In some other embodiment, for example, the first deep trench 55 which is formed on the periphery region 30 may comprises a plurality of deep slots 55a, 55b,55c and 55d separated from one another and combined to form a dash line, as shown in FIG. 3.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A wafer sawing method comprising steps as follows:
providing a wafer having a first surface and a second surface;
performing an integrated circuit fabricating process on the first surface of the wafer to define a first integrated circuit region and a periphery region surrounding around the first integrated circuit region, wherein the integrated circuit fabricating process includes an etching process used to form a first deep trench having an aspect ratio larger than 10 as well as a depth substantially ranging from one-third to two-third thickness of the wafer on the periphery region;
disposing an adhesive tape on the first surface at least covering the first integrated circuit region and the periphery region; and
imposing a tensile stress on the adhesive tape in order to make the wafer broken off along the first deep trench.

2. The wafer sawing method according to claim 1, the etching process further comprises forming a second deep trench on the first integrated circuit region.

3. The wafer sawing method according to claim 2, wherein after the second deep trench is formed by the etching process, a dielectric material is filled into the first deep trench and the second deep trench.

4. The wafer sawing method according to claim 1, wherein the etching process is performed on the periphery region to form the first deep trench having a depth substantially equal to a half thickness of the wafer.

5. The wafer sawing method according to claim 4, wherein the first deep trench formed by the etching process has a long narrow opening disposed on the periphery region.

6. The wafer sawing method according to claim 4, wherein the first deep trench formed by the etching process and disposed on the periphery region comprises a plurality of deep slots separated from one another.

7. The wafer sawing method according to claim 1, wherein after the first deep trench is formed by the etching process, a dielectric material is filled into the first deep trench.

8. The wafer sawing method according to claim 1, wherein the integrated circuit fabricating process further comprises defining a second integrated circuit region separated from the first integrated circuit region by the periphery region.

9. The wafer sawing method according to claim 1, wherein prior to imposing the tensile stress on the adhesive tape, a polishing process is performed on the second surface of the wafer in order to reduce a thickness of the wafer.

10. A wafer structure, comprising:
a wafer;
a first integrated circuit region, disposed on a first surface of the wafer;
a periphery region, surrounding around the integrated circuit region; and
a first deep trench, formed on the periphery region and having an aspect ratio larger than 10 as well as a depth substantially ranging from one-third to two-third thickness of the wafer.

11. The wafer structure according to claim 10, wherein the wafer structure further comprises a second deep trench formed on the first integrated circuit region.

12. The wafer structure according to claim 11, wherein the second deep trench has a depth substantially greater than that of the first deep trench.

13. The wafer structure according to claim 11, wherein the second deep trench has a depth substantially equal to that of the first deep trench.

14. The wafer structure according to claim 11, wherein a conductive material is disposed in the second deep trench.

15. The wafer structure according to claim 10, wherein the first deep trench has a depth substantially equal to a half thickness of the wafer.

16. The wafer structure according to claim 10, wherein the first deep trench has a long narrow opening.

17. The wafer structure according to claim 10, wherein the first deep trench comprises a plurality of deep slots separated from one another.

18. The wafer structure according to claim 10, wherein the wafer structure further comprises a second integrated circuit region separated from the first integrated circuit region by the periphery region.

19. The wafer structure according to claim 10, wherein the wafer structure further comprises a dielectric material disposed on an opening of the first deep trench.

20. The wafer structure according to claim 10, wherein the wafer further comprises a dielectric material disposed in the first deep trench and a hollow structure constituted by the dielectric material.

21. The wafer structure according to claim 10, further comprises an adhesive tape disposed on the first surface of the wafer and having a dimension substantially greater than that of the wafer.
